(19) United States
(12) Patent Application Publication
(10) Pub. No.: US 2004/0178814 A1
(43) Pub. Date: Sep. 16, 2004

(54) Semiconductor tester coupling arrangement and electrical testing method thereof

(76) Inventors: Sung-Woo Lee, Cheonan-city (KR); Duk-Soon Choi, Asan-city (KR); Jae-Hong Yun, Yongin-city (KR); In-Cheol Kim, Cheonan-city (KR)

Correspondence Address: HARNESS, DICKEY & PIERCE, P.L.C., P.O. BOX 8910, RESTON, VA, 20195, US

(21) Appl. No.: 10/799,733

(22) Filed: Mar. 15, 2004

(30) Foreign Application Priority Data
Mar. 15, 2003 (KR) 2003-16300

(51) Int. Cl. G01R 31/02

(52) U.S. Cl. 324/754

(57) ABSTRACT

A coupling arrangement for different models of semiconductor device testers manufactured by different manufacturers but capable of testing the same semiconductor device, the arrangement comprising: a mother board connectable to test heads of the different models of testers, respectively; and a device under test (DUT) board connectable between the mother board and a semiconductor device to be tested by one of the different models of tester.

### BACKGROUND OF THE INVENTION

This application claims the priority of Korean Patent Application No. 03-16300, filed on Mar. 15, 2003 in the Korean Intellectual Property Office, the disclosure of which is incorporated herein in its entirety by reference.

1. Field of the Invention

The present invention relates to a tester for electrical testing of semiconductor device and a testing method thereof, more particularly, to a tester for processing mixed signals and electrical testing method of semiconductor device thereof.

2. Description of the Related Art

After reaching a stage in manufacture at which a semiconductor device takes the form of part of a wafer or a semiconductor package (encapsulated chip), a tester then tests its electrical functions. Semiconductor devices to be tested are largely divided into three groups according to the type(s) of signal(s) operated upon, such as a digital signal semiconductor device, an analog signal semiconductor device, and a mixed signal semiconductor device (both digital and analog signals).

Since the above three groups of semiconductor elements perform different types of internal signal processing, the testers for electrical testing are also divided into three groups. That is, electrical testing of a semiconductor device which operates upon only digital signals is performed by a tester of digital signals. Electrical testing of a semiconductor device which operates upon only analog signals is performed by a tester of analog signals. Electrical testing of a semiconductor device which operates upon both types of signals is tested by a tester of mixed signals.

FIG. 1 is a block diagram of a tester for electrical testing of a semiconductor device operates upon mixed signals.

Referring to FIG. 1, the configuration of a general tester for processing mixed signals comprises a test body 10 and a test head 14 that is connected to the test body 10 by a signal cable 12. A load board connecting unit 16 is provided to mechanically bind a load board 18 to test head 14. The load board 18 is the component by which a DUT (Device Under Test) is physically and electrically connected the test body 10. The DUT is placed on sockets (not shown) on the load board 18.

Here, the load board 18 models an application circuit of which the semiconductor device will be a part and/or a printed circuit board to which the semiconductor device will be attached. In other words, the load board performs as an electro-mechanical interface. Conventionally, depending on the semiconductor devices to be tested and the particular models of testers, different types of load boards were used respectively.

In some circumstances, a semiconductor device manufacturer might use different models of testers from different manufacturers, e.g., to diversify sourcing for such testers. Testers from different manufacturers typically require differently configured load boards 18, respectively.

FIG. 2 is a plan view of a load board for a tester made by a manufacturer A according to the Related Art, FIG. 3 is a plan view of a load board for a tester made by a manufacturer B according to the Related Art, and FIG. 4 is a plan view of a load board for a tester made by a manufacturer C according to the Related Art. Here, the phrases manufacturer A, manufacturer B, and manufacturer C indicate different manufacturers who each manufacture a tester for the same semiconductor device that operates upon mixed signals.

Referring to FIGS. 2 through 4, even though the semiconductor device to be tested is the same product, the internal configurations of testers from the different manufacturers differ from one another. For this reason, it is natural that the configuration of load boards 18A, 18B and 18C are also different. Generally, load boards 18A, 18B, and 18C have connecting units for analog channel 25 and digital channel 27. However, the load boards 18A, 18B, and 18C used for testers from different manufacturers do not have a compatible configuration between the analog channel 25 and digital channel 27. Therefore, there are such cases where different models of load board 18A, 18B, and 18C are used for testing the same kind of semiconductor device product.

A load board 18 according to the related art as described above has the following drawbacks.

Firstly, for electrical testing of the same kind of semiconductor device, three different models of load boards 18A, 18B, and 18C are needed if three testers from different manufacturers are used.

Secondly, the dimensions of load board 18A for a tester from company A are 500×500 mm (width×length), which are relatively large in size. The dimensions of load board 18B for a tester from company B are 400×400 mm (width×length), which are relatively medium in size. And the dimensions of load board 18C for a tester from company C are 300×300 mm (width×length), which are relatively small in size. Such load boards 18A, 18B, and 18C are manufactured with a printed circuit board (PCB), and the costs vary according to the number of PCB layers and the size. In the future, as semiconductor devices for processing mixed signals becomes more functional and more highly integrated, the price of load boards 18A, 18B, and 18C is likely to increase. As a consequence, purchasing load boards 18A, 18B, and 18C, and their maintenance, will be costly.

Thirdly, due to the large number of load boards 18 to be operated and handled, the workload of test engineers is increased. Use of various models of load boards 18 for the same semiconductor device multiplies the aspects of designing and studying drawings related to the configuration of load board, making special requests to a manufacturer purchasing, debugging, etc. by the number of different configurations of load board 18.

### SUMMARY OF THE INVENTION

Embodiments of the present invention provide testers for testing semiconductor devices, particularly for testing one kind of semiconductor element product via different models of testers from different manufacturers. In this case, one specific model of load board (hereafter, mother board) is applicable to the different testers even if they are manufactured by different manufacturers or are different models of testers.

Embodiments of the present invention further provide a method of electrically testing a semiconductor element by using the above testers.

An embodiment of the present invention provides a coupling arrangement for coupling the same semiconductor device to different models of semiconductor device testers manufactured by different manufacturers. Such an arrangement comprises: a mother board electrically compatible with each of respective test heads of the different models of testers; and a device under test (DUT) board connectable between the mother board and a semiconductor device to be tested by one of the different models of tester.

Another embodiment of the present invention provides a method of making one or more test connections between one kind of semiconductor device and any one of multiple testers from different manufacturers that are each operable upon the one kind of semiconductor device. Such a method comprises: providing a mother board electrically compatible with each of respective test heads of the different testers; providing a device under test (DUT) board connectable between the mother board and the one kind of semiconductor device to be tested; coupling any one of the respective test heads to mother board; coupling the DUT board to the mother board; and coupling the one kind of semiconductor device to the DUB board.

Advantages enjoyed by embodiments of the present invention include: versatility, namely that a mother board can be adapted to different model testers which have been manufactured by different manufacturers, resulting in reduced cost for purchasing the mother board and reduced maintenance cost achieved by size reduction of the mother board; and decreased workload of the test engineer.

### BRIEF DESCRIPTION OF THE DRAWINGS

The above and other features and advantages of the present invention will become more apparent by describing in detail preferred embodiments thereof with reference to the attached drawings in which:

FIG. 1 is a block diagram of a tester for electrically testing a general semiconductor element for processing mixed signals according to the Related Art;

FIG. 2 is a plan view of a load board used for a tester manufactured by manufacturer A according to the Related Art;

FIG. 3 is a plan view of a load board used for a tester manufactured by manufacturer B according to the Related Art;

FIG. 4 is a plan view of a load board used for a tester manufactured by manufacturer C according to the Related Art;

FIG. 5 is a block diagram of a tester for electrically testing a semiconductor element for mixed signal processing according to an embodiment of the present invention;

FIG. 6 is a block diagram of a load board according to an embodiment of the present invention that is applicable to different model testers manufactured by various manufacturers;

FIG. 7 is a cross sectional view of FIG. 6;

FIG. 8 is a magnified cross sectional view of a locking unit in FIG. 7;

FIG. 9 is a plan view of a load board to explain a mother board according to an embodiment of the present invention;

FIG. 10 is a plan view of a mixed type mother board according to an embodiment of the present invention;

FIG. 11 is a bottom view of a mixed type mother board according to an embodiment of the present invention;

FIG. 12 is a plan view of a DUT board according to an embodiment of the present invention;

FIG. 13 is a bottom view of a DUT board according to an embodiment of the present invention;

FIG. 14 is an exploded perspective view of a relay used for a DUT board according to an embodiment of the present invention; and

FIG. 15 is a plan view when a DUT board is loaded on the mixed type mother board according to the present invention.

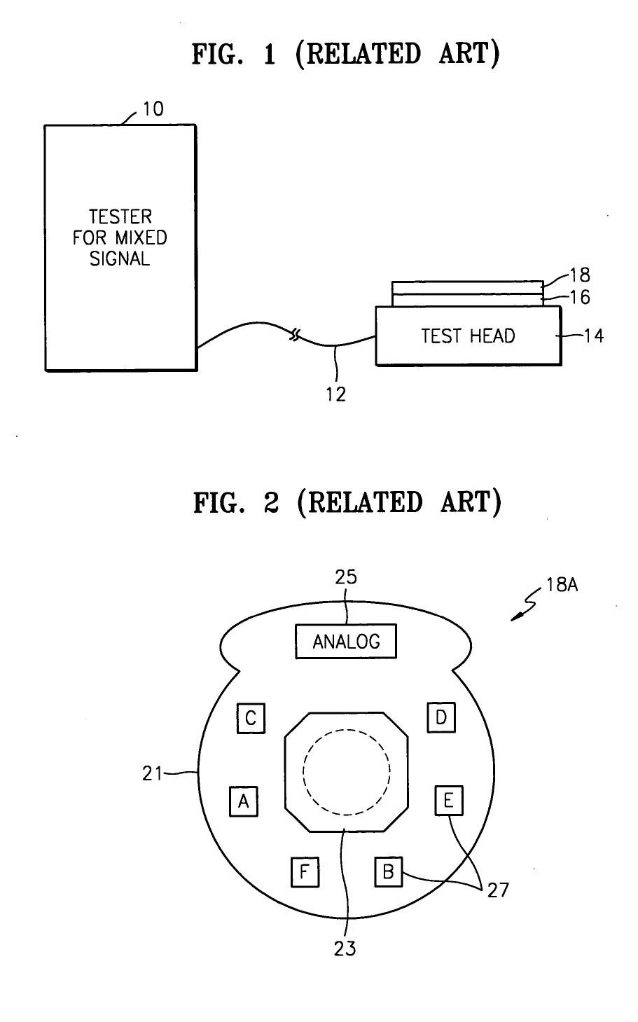

### DETAILED DESCRIPTION OF THE INVENTION

Embodiments of the present invention will now be described more fully with reference to the accompanying drawings. The present invention may, however, be embodied in many different forms and should not be construed as being limited to the embodiments set forth herein. Rather, these embodiments are provided so that this disclosure is thorough and complete and fully conveys the concept of the present invention to those skilled in the art.

A tester mentioned herein shall be interpreted in a broad sense and not be construed as being confined to a specific tester, such as a mixed tester.

The present invention can be embodied in different ways without departing from the spirit and scope of the invention. For example, in an embodiment described below, the tester is for mixed signals, but other types of testers (such as for digital signals). Also, the appearance of the mother board and DUT are shown in examples as octagonal, however, they can be other shapes such as square or circular.

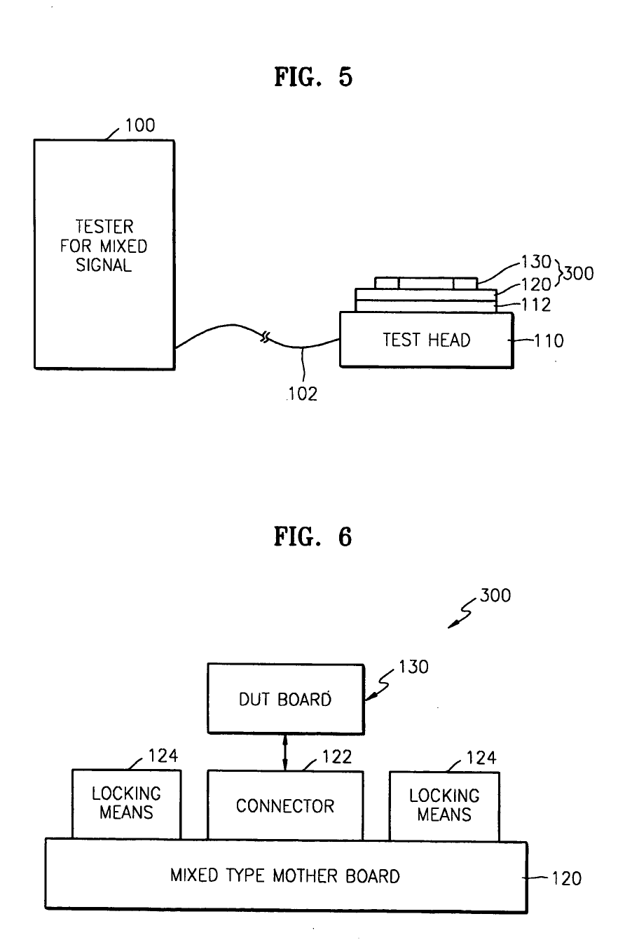

FIG. 5 is a block diagram of a tester arrangement for electrically testing a semiconductor device according to an embodiment of the present invention.

Referring to FIG. 5, the semiconductor tester arrangement comprises: different models of testers 100 (e.g., for testing mixed signals) manufactured by different manufacturers; a test head 110 which is connected to the different models of testers 100 by a signal cable 102 and plays the role of signal path between the different models of testers 100 and a Device Under test (again, DUT); a mother board 120 e.g., that can accommodate mixed signals, which is designed to be connectably compatible with each of the configurations of the different test heads 110 of the different models of testers 100, respectively; and a DUT board 130 which is applicable to mother board 112 regardless of the model of the tester assuming that a specific kind of semiconductor device product is to be electrically tested by the different model testers. A load board loading unit 112 is provided to mechanically bind mother board 112 to test head 110.

Again, for the purposes of discussion, it is assumed that the above tester 100 tests mixed signals. There are differences in configuration, etc. between a tester from one manufacturer and a tester from another despite the testers being designed to test the same semiconductor device. Embodiments of the present invention provide a mother board (a versatile type of load board) that can be used with multiple, e.g., three, testers which are manufactured by different manufacturers, as described below. Not surprisingly, the test heads 110 associated with the various testers 100 exhibit variation similar to that of the various testers 100.

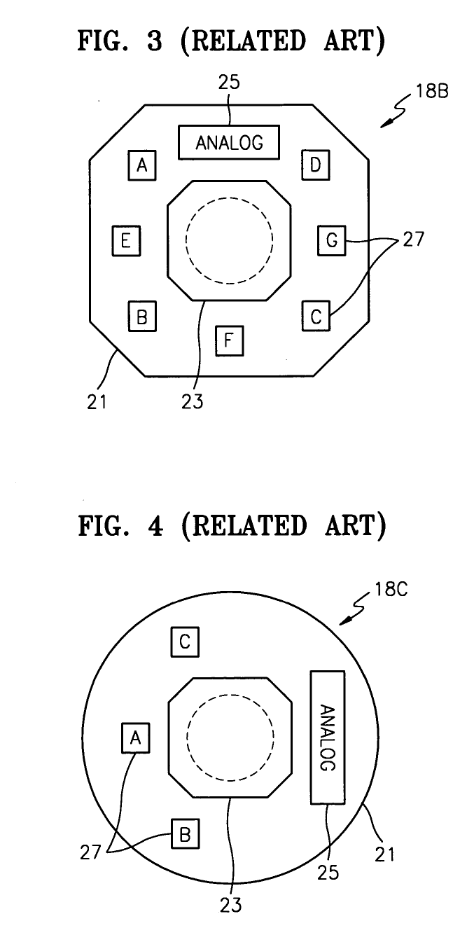

The mother board 120 is an integrated alternative to the multiple, e.g., three, different types of load boards required in the Related Art. That is, the mixed type mother board 120 has a united form for accommodating the different configurations expected of load boards that are to be used for different models tester manufactured by different manufacturers. In more detail, as contrasted with use of the different load boards 18A, 18B, and 18C of FIGS. 2 through 4 according to the Related Art, embodiments of the present invention provide an integrated form of load board 300, which can be described as a combined form of a mother board 120 (e.g., of mixed type) and a DUT board 130.

Though mother board 120 is applied to testers 100 from different manufacturers, the method of connecting mother board 120 to the load board loading units 112 differs according to the respective manufacturer of tester 100. Moreover, there is no need to change the mother board 120 even if the product type of semiconductor device to be tested varies; rather, in this circumstance, the DUT board 130 would be changed according to the variation in the semiconductor device to be tested.

FIG. 6 is a block diagram of a load board 300 that is applicable to different model testers manufactured by different manufacturers according to an embodiment of the present invention.

Referring to FIG. 6, load board 300 comprises: a mother board 120, e.g., of mixed type; a connector 122 mounted on the mixed type mother board 120 and electrically connected to a DUT board 130; one or more locking units 124 mounted on the mixed type mother board 120 by which a mechanical connection to the DUT board 130 is made; and a DUT board 130 operating on the mother board 120.

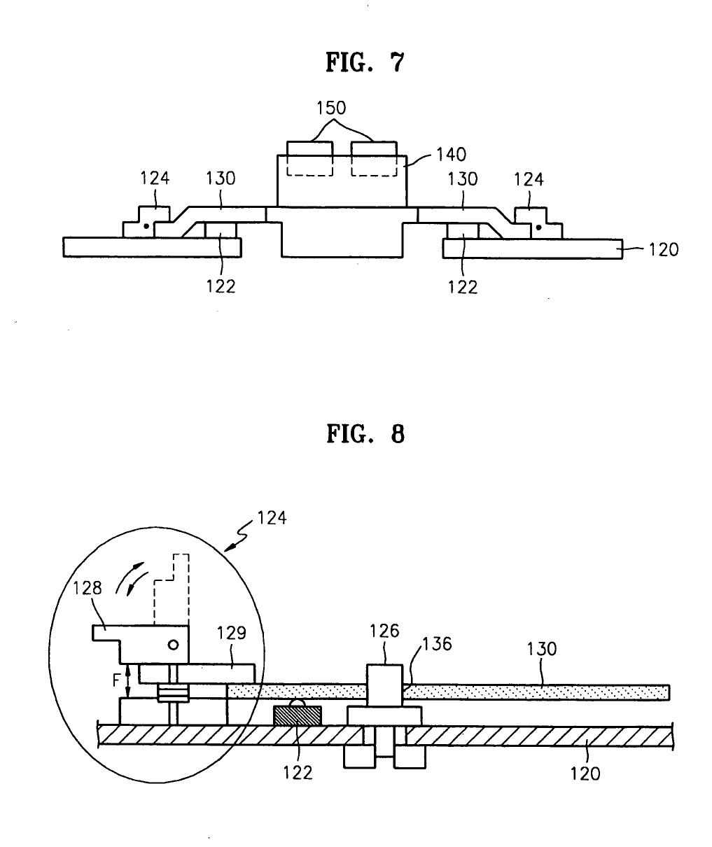

FIG. 7 is a cross sectional view of FIG. 6.

Referring to FIG. 7, a DUT board 130 is mechanically connected to the mixed type mother board 120 by a plurality of locking units 124. When a mechanical connection is made, a connector 122 that is placed on mother board 120 connects output terminals on mixed type mother board 120 to input terminals of the DUT board 130 electrically. In regard to the design of the plurality of locking units 124, mechanical wearing and convenience of connection should be considered. Also, in order to enhance the stability of an electrical signal, connector 122 can be operated stably at high frequencies, e.g., up to 1 GHz. Moreover, the dimensions of the DUT board 130 have been reduced relative to, e.g., the sizes of the Related Art (manufacturer A: 500×500 mm, manufacturer B: 400×400 mm and manufacturer C: 300×300 mm) to 200×200 mm, thereby decreasing the purchasing price.

FIG. 8 is a magnified cross sectional view of a locking unit in FIG. 7.

Referring to FIG. 8, a method of connecting mother board 120 to the DUT board 130 by a plurality of locking (or clamping) units 124 proceeds, firstly, by inserting a guide pin 126 of mother board 120 into the aperture 136 of the DUT board 130, such that an overall alignment is established. Thereafter, as indicated in the drawing, a locking latch 128 applies force to the bottom plate 129 of locking latch by moving in the direction indicated by the arrows, and then, a mechanical force is generated in direction F to create a clamping connection between mother board 120 and the DUT board 130. The force in the direction F makes and maintains an electrical connection between the connector 122 on the mixed type mother board 120 and the DUT board 130.

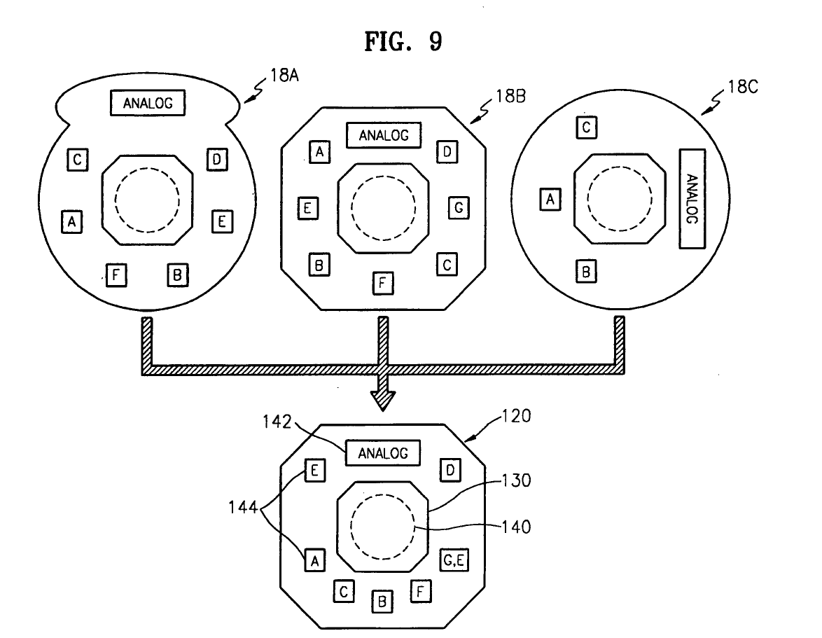

FIG. 9 is a plan view of a load board to explain the concept of a mother board according to the present invention.

Referring to FIG. 9, again, mother board 120 can be used with various configurations of load boards, e.g., 18A, 18B, and 18C which are connected to test heads 110 of different models of testers. It is noted that the specific layouts 18A, 18B and 18C (with which mother board 300 is compatible) are not limiting; mother board 300 can be layed out to be electrically compatible with other expected load-board configurations. In view of the assumption that mother board 120 is of mixed type, the reference numeral 142 indicates an analog channel terminal and the reference numeral 144 indicates a digital channel terminal. Since the analog channel terminal 142 for different model testers is the same, a direct connection method is employed. However, because different model testers have different configurations for the digital channel terminal 144, a method to accommodate all of the configurations after rearrangement is employed. A DUT board 130 is mounted on the mixed type mother board 120 as described in FIGS. 7 and 8. On top of the DUT board 130, a socket unit 140 (manufactured by a conventional method) is mounted.

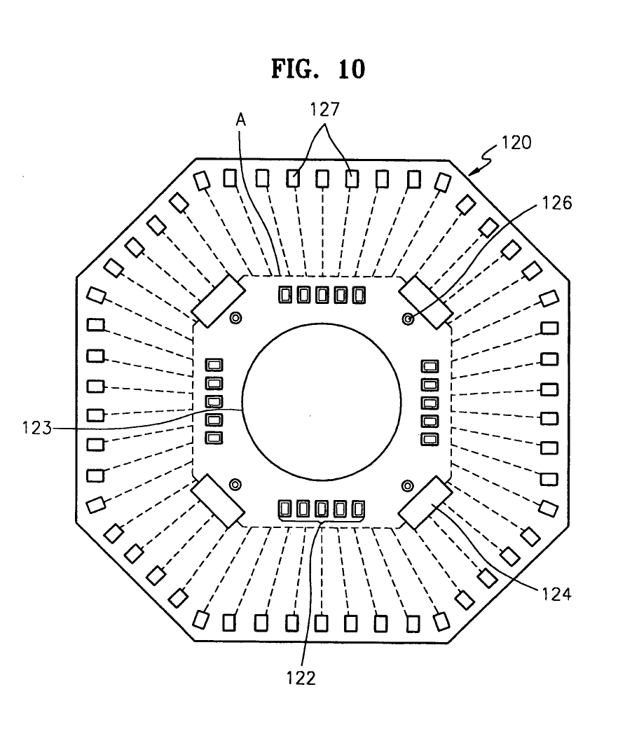

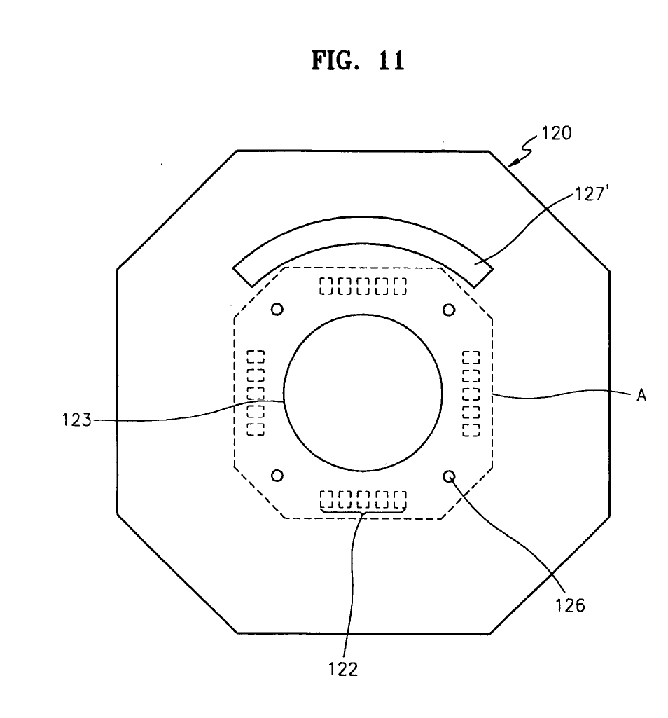

FIG. 10 is a plan view and FIG. 11 is a bottom view of mixed type mother board, respectively, according to embodiments of the present invention.

Referring to FIGS. 10 and 11, electrical signals transmitted from a tester 100 to the mixed type mother board 120 are received via the input terminals 127 of the mixed type mother board 120. Also, the received electrical signals are transmitted through mother board 120 to DUT board 130 in field A via the connectors 122, which represent output terminals for the mixed type mother board 120.

There is an aperture 123 in the center of the mixed type mother board 120. With the aid of the four guide pins 126 located in field A to which a DUT board 130 is to be connected, alignment for an electrical connection is achieved when DUT board 130 is connected. A plurality of input terminals 127 for the mixed type mother board 120 are spread out circumferentially, e.g., through 360 degrees (which can also be described as being distributed azimuthally), on the front face. However, on the back, they are gathered in a smaller predetermined, e.g., arcuate, area 127′. This variation of location can be easily achieved since the mixed type mother board 120, is formed of multiple layers of a printed circuit board. In order to avoid damage when handling or storing the mixed type mother board 120, the mixed type mother board 120 can be covered with an anti-electrostatic carrier.

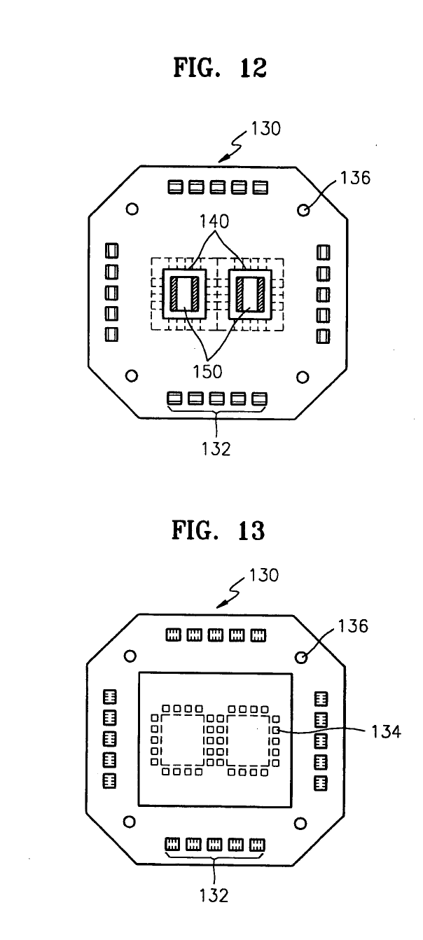

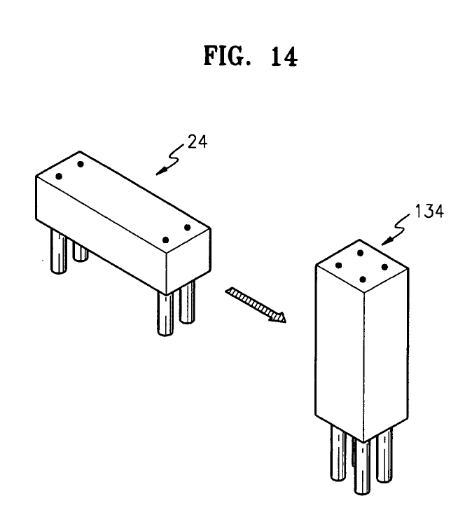

FIGS. 12 and 13 are respectively a plan view and a bottom view of DUT board 130 according to an embodiment of the present invention, and FIG. 14 is a perspective view of a relay used for a DUT board according to the present invention.

Referring to FIGS. 12 through 14, DUT board 130 (which is applicable to different model testers) comprises guide pin holes 136 for guide pins, socket units 140, and input terminals 132. The aperture 136 for guide pins is formed so as to be aligned with the mixed type mother board 120 when connected thereto.

Each socket unit 140 is a mounting portion for loading and locking the semiconductor device, that is, a DUT, to be tested. In FIGS. 12-13 a DUT board having two socket units 140 is described as an example, however, the number of sockets can be increased or decreased. Also, the socket-shape of socket units 140 varies according to the shape of the semiconductor device (or DUT) 150 to be tested.

A plurality of input terminals 132 of a DUT board are connected to the connector 122 of the mixed type mother board 120. If an electrical signal is transmitted from the tester 110 to the DUT board 130, the DUT board 130 receives the electrical signal through the input terminals 132 and conveys the signal to the DUT 150 that is located in the socket units 140.

Also, a plurality of relays are used in socket units 140, which are located on the backside of the DUT board 130. The dimensions of the DUT board 130 can be, e.g., 200×200 mm, which are relatively small in comparison to the Related Art load boards 18A, 18B and 18C. In order to minimize the dimensions of the DUT board 130, according to an embodiment of the present invention, the type of relay is modified from a horizontal type relay 24 used in the Related Art to a vertical type relay 134.

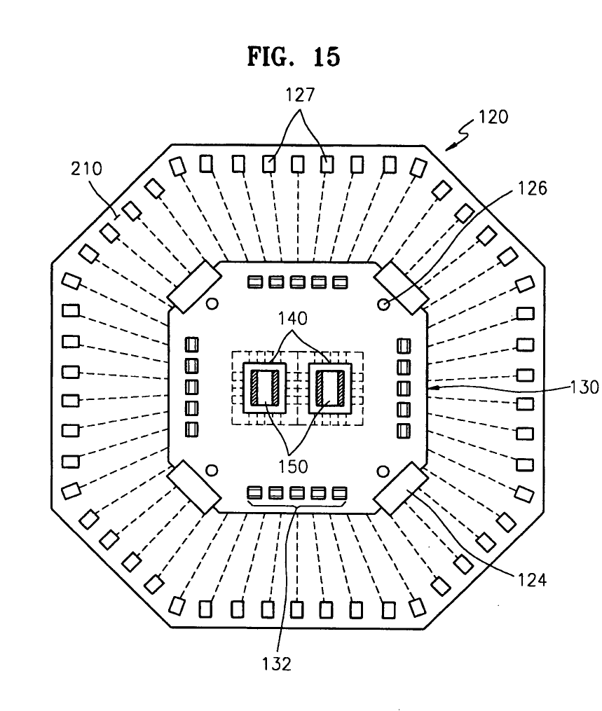

FIG. 15 is a plan view when DUT board 130 is mounted on the mixed mother board according to the present invention.

Referring to FIG. 15, it is seen that a DUT board 130 is connected to a mixed type mother board 120 by a plurality of guide pins 126 and locking units 124 which are placed on the mixed type mother board 120. The path of an electrical signal in the mother board 300 is such that a signal from a tester 100 is transferred to a test head 110, then the test head 110 transfers the signal to input terminals 127 of mixed type mother board 120, next, from terminals 127 to terminals 127 of mixed type mother board 120, next, from terminals 127′ of mixed type mother board 120 to input terminals 132 of DUT board 130, and finally from the input terminals 132 of the DUT boards 130 to the DUT 150 mounted on socket units 140. Once the input of an electrical signal to the DUT is completed, the electrical signal is output in the opposite direction to the tester.

Therefore, according to embodiments of the present invention, firstly, there is an advantage in that adaptability of a mother board (a versatile load board) to different models of tester is made possible since the same mother board can be used with different models of testers that are manufactured by various manufacturers. Secondly, minimized dimensions of the mother board and the reduction in the number of load boards represented by the mother board achieves decreased purchase costs (relative to purchasing multiple load boards) and maintenance costs. Thirdly, as contrasted to the Related Art, the need to design and manage different models of a load board can be reduced to one model of a load board, thereby decreasing the workload of the engineer.

This invention may be embodied in many different forms and should not be construed as being limited to the embodiments set forth herein. Rather these embodiments are provided so that this disclosure is thorough and complete and fully conveys the concept of the invention to those skilled in the art.

What is claimed is:

1. A coupling arrangement for coupling the same semiconductor device to different models of semiconductor device testers manufactured by different manufacturers, the arrangement comprising:
a mother board electrically compatible with each of respective test heads of the different models of testers; and
a device under test (DUT) board connectable between the mother board and a semiconductor device to be tested by one of the different models of tester.

2. The coupling arrangement of claim 1 further comprising:
a load board loading unit to mechanically bind the mother board to any one of the test heads.

3. The coupling arrangement of claim 1, wherein the mother board provides signal paths for mixed signals, respectively.

4. The coupling arrangement of claim 1, wherein a plurality of locking units are placed on the mother board for mechanically connecting the DUT board to the mother board.

5. The coupling arrangement of claim 4, wherein an electrical connection between the respective test head and the semiconductor device is made through a connector on the mother board.

6. The semiconductor element tester of claim 4, wherein the plurality of locking units has the same shape regardless of the particular manufacturer of the tester.

7. The semiconductor device tester of claim 1, wherein the DUT board includes vertical type relays.

8. A method of making one or more test connections between one kind of semiconductor device and any one of multiple testers from different manufacturers that are each operable upon the one kind of semiconductor device, the method comprising:
providing a mother board electrically compatible with each of respective test heads of the different testers;
providing a device under test (DUT) board connectable between the mother board and the one kind of semiconductor device to be tested;
coupling any one of the respective test heads to the mother board;
coupling the DUT board to the mother board; and
coupling the one kind of semiconductor device to the DUT board.

9. The coupling arrangement of claim 1, further comprising:
mechanically binding the mother board heads via a load board loading unit.

10. The method of claim 8, wherein the mother board provides signal paths for different models of testers of mixed signals, respectively.

11. The method of claim 8, further comprising binding the DUT board to the mother board via a plurality of locking units.

12. The coupling arrangement of claim 1, further comprising:
arranging a first side of the mother board to have terminals for test signal paths distributed azimuthally around the center thereof, and arranging a second side of the mother board to have terminals for test signal paths, respectively, gathered into a relative smaller predetermined area.

13. The coupling arrangement of claim 12, wherein the predetermined area is arcuate in shape.

14. The method of claim 8, further comprising electrically connecting test signal paths through the mother board to test signal paths on the DUT board via aligning conductive terminals.
